(19) United States
(12) Patent Application Publication
(10) Pub. No.: US 2002/0053421 A1
(43) Pub. Date: May 9, 2002

(54) Heat dissipating structure for electronic apparatus

(75) Inventors: Katsumi Hisano, Yokohama-Shi (JP); Hideo Iwasaki, Kawasaki-Shi (JP); Yutaka Sata, Tokyo-To (JP); Hiroshi Ubukata, Oume-Shi (JP); Sadao Makita, Saitama-Ken (JP); Kentaro Tomioka, Saitama-Ken (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Kawasaki-Shi (JP)

(21) Appl. No.: 10/022,873

(22) Filed: Dec. 20, 2001

Related U.S. Application Data
(62) Division of application No. 09/151,031, filed on Sep. 10, 1998.

(30) Foreign Application Priority Data
Sep. 10, 1997 (JP) 9-245700
Sep. 10, 1997 (JP) 9-245724

(51) Int. Cl. F28F 7/00; F28D 15/00; G06F 1/20; H05K 5/00; H05K 7/20

(52) U.S. Cl. 165/104.33; 165/80.3; 361/700; 361/704; 361/687

(57) ABSTRACT

The present invention is intended to improve the heat radiating performance of an electronic apparatus provided with semiconductor devices which generate heat at a high rate. An air passage (20) is formed in a case 10, and a fan (6) produces air currents in the air passage (20). Heat generated by a heat-generative part (1) mounted on a circuit board (2) is transferred to a wall (21) included in walls defining the air passage (20) by a heat transfer member (3), such as a heat pipe, and is carried outside the case 10 by cooling air flowing through the air passage (20).

### BACKGROUND OF THE INVENTION

1. Field of the Invention

The present invention relates to a heat dissipating structure for an electronic apparatus, such as a notebook personal computer.

2. Description of the Related Art

FIG. 31 illustrates the internal configuration of a general notebook personal computer (hereinafter referred to as “notebook PC”). Component parts including a printed circuit board 302 mounted with semiconductor devices including an MPU (Micro Process Unit), a HDD (Hard Disk Drive) 303, an interface unit 304 for a PC (Personal Computer) card and a battery 305 are stored in a high density in the case of a main unit 301. The component parts which generate a large quantity of heat, such as the MPU and such, (hereinafter referred to as “heat-generative part(s)”) are mounted on the printed circuit board 302. The case is provided with air inlets and an air outlet, and a fan 306 is disposed near the air outlet to produce air currents flowing from the air inlets through the interior of the case toward the air outlet. The heat-generative parts are cooled by a cooling system using the air currents produced by the fan 306.

Recently developed high-performance MPUs, i.e., heat-generative parts, generate an increased amount of heat. Therefore, some notebook PCs provided with such a high-performance MPU cannot satisfactorily be cooled by the conventional cooling system.

If the fan is disposed near the air outlet as shown in FIG. 31 by way of example, a negative pressure is produced in the case and, consequently, air is sucked into the case through openings other than the intended air inlets, such as gaps around slots and connectors. If air is sucked into the case through such open spaces in addition to sucking through the intended air inlets, air flows through a wide area in the case at low velocities, so that it is difficult to cool the heat-generative parts effectively. Since air flows in the case cannot precisely be known if air flows through a wide area, it is difficult to design an appropriate heat dissipating structure for dissipating heat generated by the component electronic devices.

Another cooling system may take air into the case by a fan disposed near an air inlet. This cooling system, however, is unable to cool effectively component parts other than those disposed near the fan. If the component parts are disposed in a high density in the case, the fan can be installed in only a space available in a peripheral region of the case. However, if the heat-generative part is a CPU, it is sometimes difficult to dispose the CPU in a peripheral region of the case because the CPU is mounted on a printed circuit board.

When the conventional cooling system is employed, it is possible that foreign matters, such as dust and paper clips, entered the case through the air inlets and the air outlet are dispersed in the case and adhere to any parts of the printed circuit board and the devices may possibly be damaged by the short-circuiting effect of conductive foreign matters.

### SUMMARY OF THE INVENTION

Accordingly, it is a first object of the present invention to form an improved cooling air passages in a case of an electronic apparatus to enable the highly efficient dissipation of heat generated by the electronic apparatus.

A second object of the present invention is to enable the highly efficient dissipation of heat generated by an electronic apparatus by dissipating heat through a case other than a case of the electronic apparatus in addition to dissipating heat through the case of the electronic apparatus.

With the foregoing object in view, according to a first aspect of the present invention, an electronic apparatus is provided which includes: a case containing a heat-generative part; walls defining a passage in the case, the passage is adapted to carry a cooling medium therethrough; a fan for producing a flow of the cooling medium in the passage; and a heat transfer member for transferring heat generated by the heat-generative part to the cooling-medium flowing through the passage; wherein a heat generated by the heat-generative part is conveyed outside the case by the cooling medium flowing through the passage.

According to a second aspect of the present invention, an electronic apparatus is provided which includes: a case containing a heat-generative part; walls defining a passage in the case, the passage being adopted to carry a cooling medium therethrough; a fan for producing a flow of the cooling medium in the passage; and a circuit board serving as one of the walls and disposed with a heat-generative part mounted thereon such that at least part of the heat-generating part lies in the passage; wherein a heat generated by the heat-generative part is conveyed outside the case by the cooling medium flowing through the passage.

According to a third aspect of the present invention, an electronic apparatus is provided which includes: a first case containing a heat-generative part; a second case connected to the first case; a joint structure connecting together the first and the second case so that the first and the second case are able to turn relative to each other about a predetermined axis; a heat radiating means provided at the second case; and a hinge joint serving as at least part of the joint structure and being capable of transmitting heat, and the hinge joint having a bearing member thermally connected to one of both of the heat radiating means and the heat-generative part, and a heat transfer member having one side provided with a pivotal member pivotally fitted in the bearing member and the other side thermally connected to the other of both of the heat radiating means or the heat-generative part.

According to a fourth aspect of the present invention, an electronic apparatus is provided which includes: a first case containing a heat-generative part; a second case connected to the first case; a joint structure joining together the first and the second case so that the first and the second case are able to turn relative to each other about a predetermined axis; a heat radiating means placed in the second case; and a heat transfer member having opposite ends connected respectively to the heat-generative part and the heat radiating means, the heat transfer member including a flexible section haing a flexibility so as not to obstruct the turning of the first and the second case relative to each other.

### BRIEF DESCRIPTION OF THE DRAWINGS

FIG. 1 is a perspective view of a notebook PC, i.e., an electronic apparatus, in a first embodiment according to the present invention;

FIG. 2 is a sectional view taken on line II-II in FIG. 1;

FIG. 3 is a sectional view taken on line III-III in FIG. 2;

FIG. 4 is a sectional view of assistance in explaining another method of connecting a top wall and a heat transfer member;

FIG. 5 is a sectional view taken on line V-V in FIG. 1 of assistance in explaining a method of connecting a heat transfer member and a heat-generative part;

FIG. 6 is a sectional view of a structure defining air passages;

FIGS. 7(a) and 7(b) are sectional views showing different dispositions of a fan;

FIG. 8 is a sectional view of assistance in explaining a method of directly discharging heat into an air passage by a heat transfer member;

FIG. 9 is a perspective view of a notebook PC, i.e., an electronic apparatus, in a second embodiment according to the present invention;

FIG. 10 is a sectional view taken on line X-X in FIG. 9;

FIG. 11 is a sectional view taken on line XI-XI in FIG. 9;

FIG. 12 is a fragmentary sectional view of a case containing a heat-generative part not provided with a heatsink;

FIG. 13 is a fragmentary sectional view of a case containing a heat-generative part mounted on separate circuit boards;

FIG. 14 is a fragmentary sectional view of a case of assistance in explaining a method of attaching a heatsink to a heat-generative part;

FIG. 15 is a fragmentary sectional view of a case of assistance in explaining air passages;

FIG. 16 is a schematic partly cutaway perspective view of an essential part of a notebook PC, i.e., an electronic apparatus, in a third embodiment according to the present invention;

FIG. 17 is an enlarged perspective view of a hinge joint shown in FIG. 16;

FIG. 18 is a schematic partly cutaway perspective view of an essential part of a notebook PC, i.e., an electronic apparatus, in a fourth embodiment according to the present invention;

FIG. 19 is a perspective view of a hinge joint shown in FIG. 18;

FIG. 20 is a schematic partly cutaway perspective view of an essential part of a notebook PC, i.e., an electronic apparatus, in a fifth embodiment according to the present invention;

FIG. 21 is a sectional view of a connecting structure for connecting a bearing member and a heat pipe;

FIG. 22 is a sectional view of a hinge joint included in an electronic apparatus in a sixth embodiment according to the present invention;

FIG. 23 is a sectional view of a hinge joint included in an electronic apparatus in a seventh embodiment according to the present invention;

FIG. 24 is a schematic partly cutaway perspective view of an essential part of a notebook PC, i.e., an electronic apparatus, in an eighth embodiment according to the present invention;

FIG. 25 is a sectional view of a hinge joint shown in FIG. 24;

FIG. 26 is a schematic partly cutaway perspective view of an essential part of a notebook PC, i.e., an electronic apparatus, in a ninth embodiment according to the present invention;

FIG. 27 is a perspective view of a hinge joint shown in FIG. 26;

FIG. 28 is a schematic partly cutaway perspective view of an essential part of a notebook PC, i.e., an electronic apparatus, in a tenth embodiment according to the present invention;

FIG. 29 is a perspective view of a flexible joint;

FIG. 30 is a schematic partly cutaway perspective view of an essential part of a notebook PC, i.e., an electronic apparatus, in an eleventh embodiment according to the present invention; and

FIG. 31 is a perspective view of a conventional heat dissipating structure included in an electronic apparatus.

### DESCRIPTION OF THE PREFERRED EMBODIMENTS

In the preferred embodiments of the present invention described hereinafter, notebook PCs are considered to be pieces of electronic apparatus embodying the present invention. The present invention is not limited in its practical application to the embodiments thereof specifically described herein but may be applied to electronic apparatus comprising component parts arranged in a high density, particularly, to portable information processing apparatus.

First Embodiment

A notebook PC in a first embodiment according to the present invention will be described with reference to FIGS. 1 to 7.

Referring to FIG. 1, a notebook PC has a main unit M and a display unit D connected by hinges to the main unit M for turning relative to the main unit M. In FIG. 1, a case 10 included in the main unit M, and the display unit D are indicated by alternate long and two short dashes lines. Contained in the case 10 of the main unit M are component parts including a circuit board 2 mounted with a component part 1 which generates a large amount of heat (hereinafter referred to as “heat-generative part”) , such as a MPU, a HDD 90, an interface unit 91 for a PC card and a battery 92. The case 10 is formed of a ABS (acrylonitrile-butadiene-styrene) resin. Alternatively, the case 10 may be formed of a magnesium alloy.

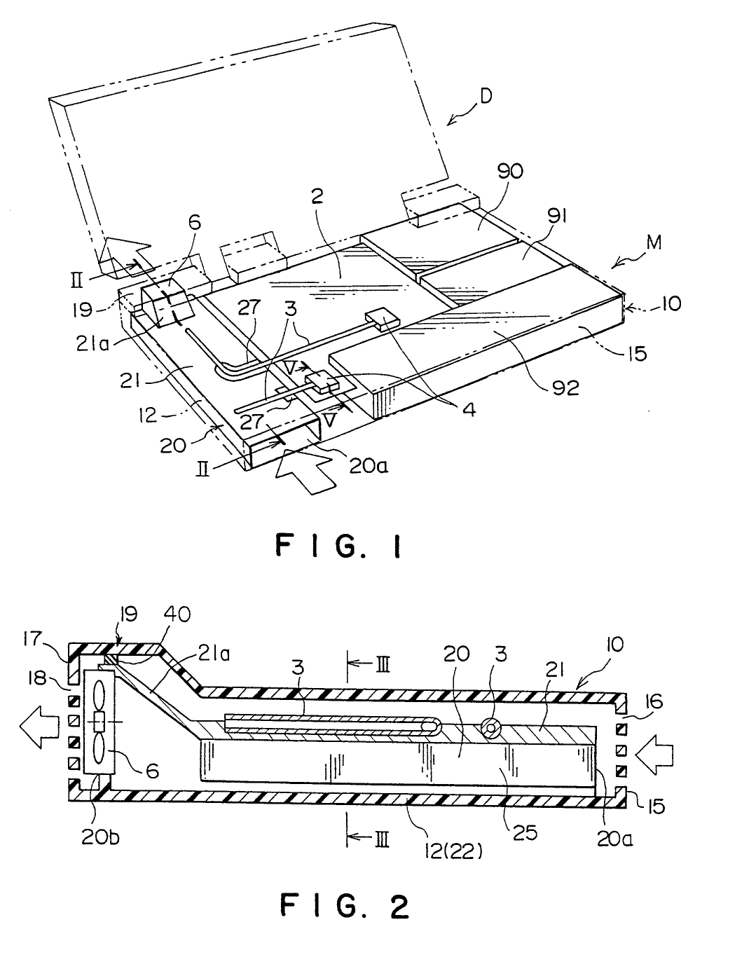

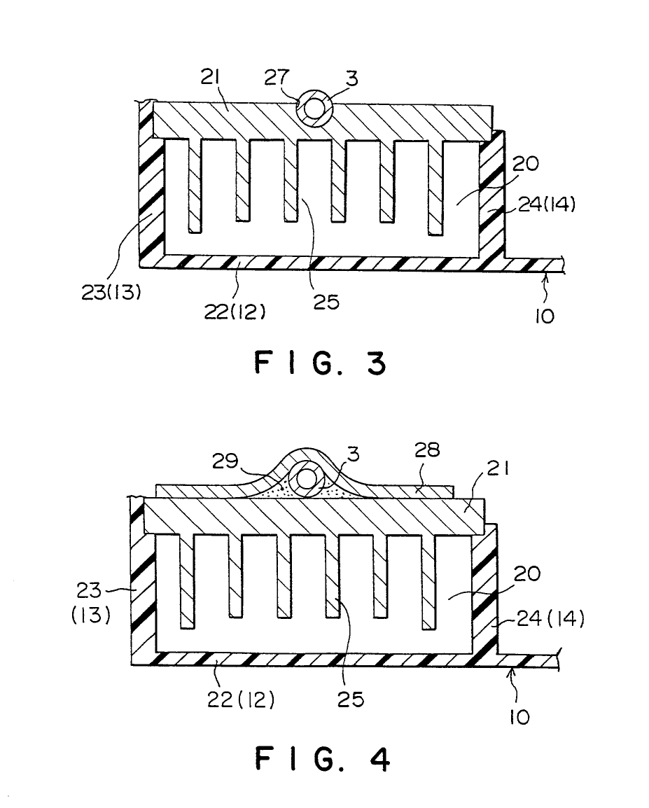

As shown in FIGS. 1 and 2, a duct structure defining an air passage 20 is formed in one side region, i.e., a left side region as viewed in FIG. 1, of the case 10 of the main unit M so as to extend along a side wall 12 of the case 10 from the side of a front wall 15 toward the side of a back wall 17. As shown in FIG. 3, the air passage 20 is defined by a plurality of walls, i.e., a top wall 21, a bottom wall 22, and a pair of side walls 23 and 24. The bottom wall 22 and the side walls 23 and 24 form a channel structure having an open upper end, and the top wall 21 is put on the open upper end of the channel structure to form a duct structure having the air passage 20. The bottom wall 22 and the side walls 23 and 24 amongst walls 21, 22, 23 and 24 are the integral parts the case 10 formed of a magnesium alloy by die-casting (or formed of an ABS resin by injection molding). As best shown in FIG. 3, a side wall 13 of the case 10 serves as the side wall 23, and a bottom wall 12 of the case 10 serves as the bottom wall 22. A rib 14 perpendicular to the bottom wall 12 of the case 10 serves as the side wall 24.

As shown in FIG. 2, the opposite longitudinal ends of the duct formed of the walls 21, 22, 23 and 24 are open; one of the opposite longitudinal ends, i.e., the right end as viewed in FIG. 2, serves as an air inlet 20a through which cooling air is sucked into the duct structure (air inlet of the air passage 20), and the other end, i.e., the left end as viewed in FIG. 2, serves as an air outlet 20b through which cooling air flows out of the duct structure (air outlet of the air passage 20).

An air entrance 16 is formed in a part of a front wall 15 of the case 10 opposite the air inlet 20a of the duct structure, and an air exit 18 is formed in a part of the back wall 17 of the case 10 opposite the air outlet 20b of the duct structure. The air entrance 16 and the air exit 18 comprise fine slits aligned in a row, or a number of fine through holes arranged in a grid pattern, in order to prevent the infiltration of foreign matters into the case 10.

A rear part of the case 10 of the main unit M, i.e., a part of the case 10 on the side of the rear end of the duct structure having the air outlet 20b, is protruded upward to form a protuberance 19 for supporting the display unit D. As shown in FIG. 2, a part of the interior of the main unit M corresponding to the protuberance 19 and to the rear end of the air passage 20 has an increased height, and the height of the air passage 20 is increased toward the rear end.

A fan 6 is attached to the rear end of the duct structure provided with the air outlet 20b and lying in the protuberance 19 with its rotating shaft extended in a horizontal position. Since the fan 6 is disposed in the protuberance 19 for supporting the display unit D, the diameter of the fan 6 may be greater than the thickness of an essential part of the main unit M, i.e., a part of the main unit M excluding the protuberance 19. Therefore, the cooling air can flow at a high flow rate and a high velocity through the air passage 20, and the essential part of the main unit M can be formed in a relatively small thickness.

A partition 40 is provided between the case 10, and the side wall 24 and the top wall 21 (including a protuberant part 21a corresponding to the protuberance 19 containing the fan 6) at the side of air outlet 20b. The partition 40 prevents the reverse flow of hot air discharged through the air outlet 20b into the case 10.

Only the top wall 21 among the walls 21, 22, 23 and 24 is made of a magnesium alloy. As shown in FIG. 3, the top wall 21 is provided with a plurality of fins 25 projecting into the air passage 20 and extending in the flowing direction of air in the air passage 20, i.e., a horizontal direction as viewed in FIG. 2. The top wall 21 need not necessarily be formed of the magnesium alloy but may be formed of a metal other than the magnesium alloy or of a ceramic material having a high thermal conductivity, such as alumina or aluminum nitride.

As shown in FIG. 3, grooves 27 are formed in the upper surface of the top wall 21. Heat pipes 3 (heat transfer members) are placed in the grooves 27, respectively. Straight parts of each heat pipe 3 are pressed in the groove 27. One of the heat pipes 3 has a curved part. As the curved part of the heat pipe 3 is formed in a low dimensional accuracy, a part of the groove 27 corresponding to the curved part the heat pipe 3 is formed in a width greater than that of the heat pipe 3 (The widen parts of the grooves 27 is indicated at 27 in FIG. 1). The heat pipes 3 may be fixed to the grooves 27 by caulking instead of by press fitting.

The heat pipes 3 may be connected to the top wall 21 by a method other than that illustrated in FIG. 3. For example, the heat pipe 3 may be attached to the top wall 21 by placing the heat pipe 3 on the flat upper surface of the top wall 21, placing a metal sheet 28 on the upper surface of the top wall 21 so as to cover the heat pipe 3, and bonding the heat pipe 3 and the metal sheet 28 to the top wall 21 with a heat conductive adhesive 29 as shown in FIG. 4. The heat pipe 3 fitted in the groove 27 as shown in FIG. 3 may be covered with the metal sheet 28.

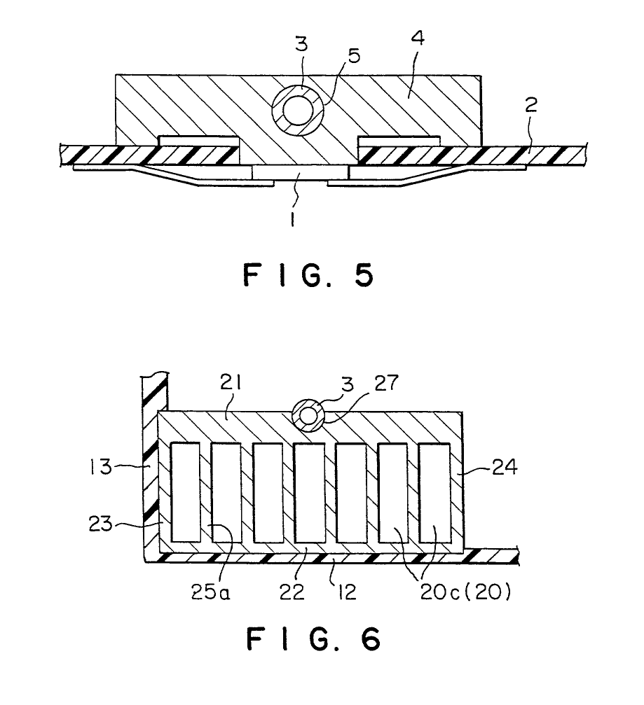

As shown in FIGS. 1 and 5, one part of the heat pipe 3 having the other part mechanically and thermally connected to the top wall 21 of the duct is inserted in a bore 5 formed in a heat transfer block 4 formed of a material having a high thermal conductivity, such as a metal, and mechanically and thermally connected to the heat-generative part 1. Preferably, the part of the heat pipe 3 is forced into the bore 5.

The efficiency of heat transfer from the heat transfer block 4 to the heat pipe 3 and from the heat pipe 3 to the top wall 21 can be improved by applying a heat-conductive paste (heat-conductive grease) or a heat-conductive adhesive to the contact surfaces of the heat pipes 3, the top wall 21 and the heat transfer block 4 when assembling the heat pipes 3, the top wall 21 and the heat transfer block 4.

As shown in FIG. 6, the duct structure may be formed by an integrally-formed tube having a plurality of cavities 20c which are separated each other by partitioning elements 25a. The cavities 20c are used for the air passage 20. The integrally-formed tube may be an extrusion tube of aluminum or magnesium.

The operation of the first embodiment thus constructed will be described below.

The fan 6 is driven for operation to take the ambient air (cooling air) through the air entrance 16 formed in the front wall 15 of the case 10 of the main unit M into the case 10. The cooling air is sucked through the air inlet 20a into the air passage 20, flows through the air passage 20 and is discharged through the air outlet 20b from the air passage 20. Then the cooling air flows out of the case 10 through the air exit 18 formed in the rear wall of the case 10. Thus, currents of the cooling air flowing from the air inlet 20a toward the air outlet 20b are produced in the air passage 20. The flow rate and the velocity of the cooling air in the air passage 20 are dependent on the rotating speed of the fan 6 and the sectional shape of the air passage 20.

A small space is formed between the air inlet 20a and the air entrance 16 of the case 10. Therefore, air is sucked at a certain flow rate from the interior of the case 10 through the air inlet 20a into the air passage 20 by the agency of a negative pressure produced in the air passage 20 by the fan 6. Such a flow of air in the interior of the case 10 can be used for cooling the component parts which generate heat at a relatively low rate.

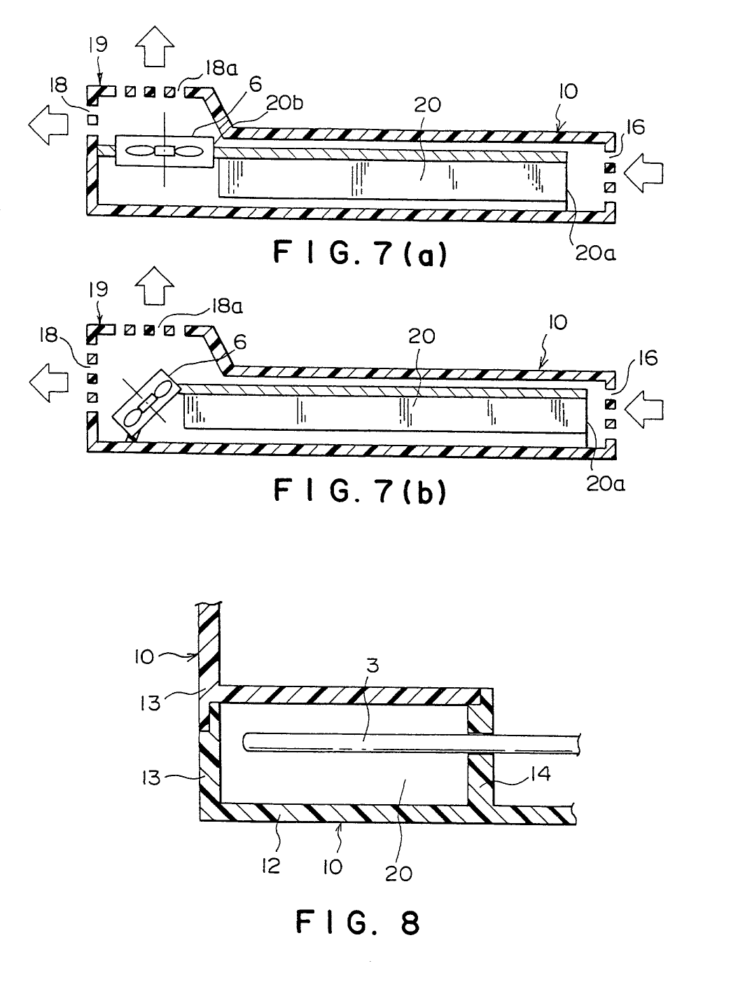

As mentioned above, the partition 40 is fitted in the joint between the case 10, and the side wall 24 and the top wall 21 to seal a space in the case 10 between the air outlet 20b and the air exit 18 to prevent the reverse flow of hot air discharged through the air outlet 20b into the case 10. If the space between the air outlet 20b and the air exit 18 is very narrow or a rise in the temperature of the cooling air while the cooling air flows through the air passage 20 is small, the partition 40 may be omitted as shown in FIG. 7.

Heat generated by the heat-generative part 1 mounted on the circuit board 2 is transferred through the heat transfer block 4, the heat pipe 3 and the top wall 21 to the fins 25 and is transferred from the fins 25 to the cooling air flowing through the air passage 20.

In the electronic apparatus in the first embodiment, the air passage 20 substantially isolated from the interior of the case 10 is defined in a region of the interior of the case 10 by the walls 21, 22, 23 and 24, especially by the walls 21, 24. In addition, the fan 6 produces forced currents of cooling air in the air passage 20. Accordingly, the cooling air flows through the air passage 20 at a sufficiently high flow rate and a sufficiently high velocity. Since the particularly heat-generating heat-generative parts 1 are connected selectively and thermally to the cooling air flowing through the air passage 20 by the heat pipes 3, the heat-generative parts 1 can efficiently be cooled.

Since the air passage 20 is substantially isolated from the interior of the case 10, the air passage 20 can be formed in an appropriate sectional shape and the fan 6 may be of an appropriate air blowing ability to produced currents of cooling air of a desired flow rate and a desired velocity in the air passage 20. Since the rate of heat radiation can easily be calculated, the heat dissipating design for electronic apparatus can easily be done.

Since the heat-generative parts 1 are connected to the air passage 20 by the heat pipes (heat transfer members) 3, the positional relation between the air passage 20 and the heat-generative parts 1 can optionally be determined. Accordingly, the heat-generative parts 1 can efficiently be cooled without being subject to the arrangement of the component parts in the case 10.

Although there is a space between the air inlet 20a of the duct structure and the air entrance 16 of the case 10 as shown in FIG. 2 in the first embodiment, the space, similarly to the space around the air outlet 20b, may be sealed by a partition provided between the walls 21 and 24 defining the duct structure, and the case 10 to isolate the air passage 20 of the duct structure perfectly from the interior space of the case 10. When the air passage 20 is thus perfectly isolated from the interior space of the case 10, the infiltration of foreign matters through the air entrance 16 into the case 10 can perfectly be prevented.

Even if spaces are formed between the air inlet 20a of the duct structure and the air entrance 16 of the case 10 and between the air outlet 20b of the duct structure and the air exit 18 of the case as in the first embodiment as shown in FIG. 2, dust floating in the atmosphere substantially surely flows into the air passage 20 and hence the accumulation of dust on the circuit board 2 can effectively prevented. Even if foreign matters not floating in the atmosphere enter the casing 10, the foreign matters accumulate on the circuit board 2 at a very low probability.

The fan 6 need not necessarily be disposed with its axis parallel to the longitudinal axis of the air passage 20 as indicated by an alternate long and short dash line in FIG. 2. For example, if, as shown in FIG. 7(a), the protuberance 19 of the main unit M for holding the display unit D can be formed in a great width , i.e., a lateral dimension in FIG. 7(a), and the axis of a hinge mechanism for pivotally joining the display unit D to the main unit M can be extended in a front part (a right-hand part as viewed in FIG. 7(a)) of the protuberance 19, an air exit 18a may be formed in an upper wall of the protuberance 19, and the fan 6 may be disposed with its axis extended vertically to discharge air from the air passage 20 through the air exit 18a. When the fan 6 is disposed in such a position, the air passage 20 of the duct structure can be formed in a small height and a heat dissipating structure thus constructed can be applied to a thin electronic apparatus. Since the air exit 18a is always open regardless of the position of the display unit D, the cooling air can smoothly discharged through the air exit 18a.

The fan 6 may be disposed with its axis extended at an angle to the horizontal axis of the air passage 20 as shown in FIG. 7(b). When the fan 6 is disposed as shown in FIG. 7(b), the duct structure including the fan 6 can be formed in a small height.

The duct structure defining the air passage 20 may be formed of members not including any parts of the case 10. For example, the duct structure may be an extruded metal pipe having a plurality of hollows serving as the air passage 20, formed by extruding a metal, and disposed in the case 10 as shown in FIG. 6.

The air passage 20 need not necessarily be straight and extended in one side region, i.e., a left side region as viewed in FIG. 1, of the case 10 of the main unit M. The air passage 20 may be formed in another region of the case 10 or may be curved or bent. The duct structure may be provided with a plurality of air inlets and a single air outlet and a plurality of passages extending from the plurality of air inlets toward the air outlet may be joined to form a single passage.

Some of the walls defining the air passage may be portions of electronic components, such as the case of the HDD 90, contained in the case 10. The top wall 21 of the duct structure may be formed integrally with the case 10, and the heat pipe 3 may be inserted through the rib 14 into the air passage 20 to make the heat pipe 3 exchange heat directly with the cooling air flowing through the air passage 20, as shown in FIG. 8.

A heat transfer member made of a heat conductive material, such as a metal bar or a carbon fiber bundle, may be used instead of the heat pipe 3.

Second Embodiment

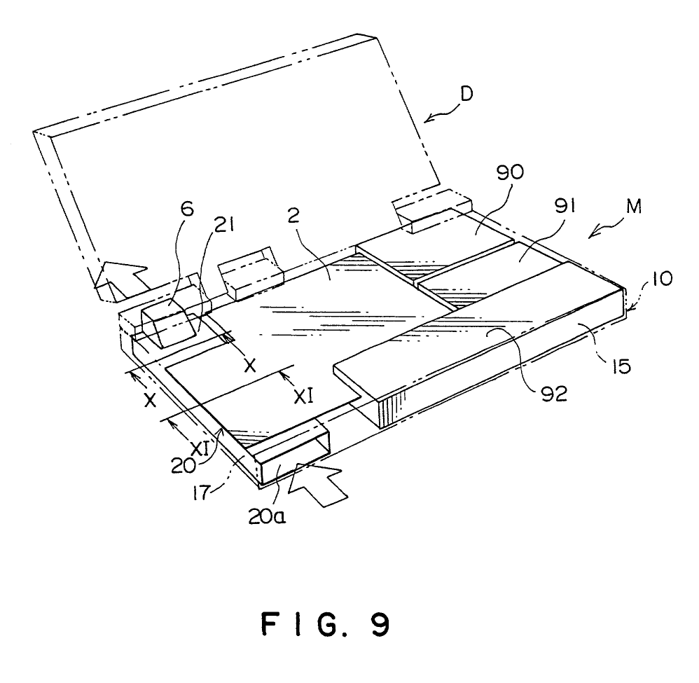

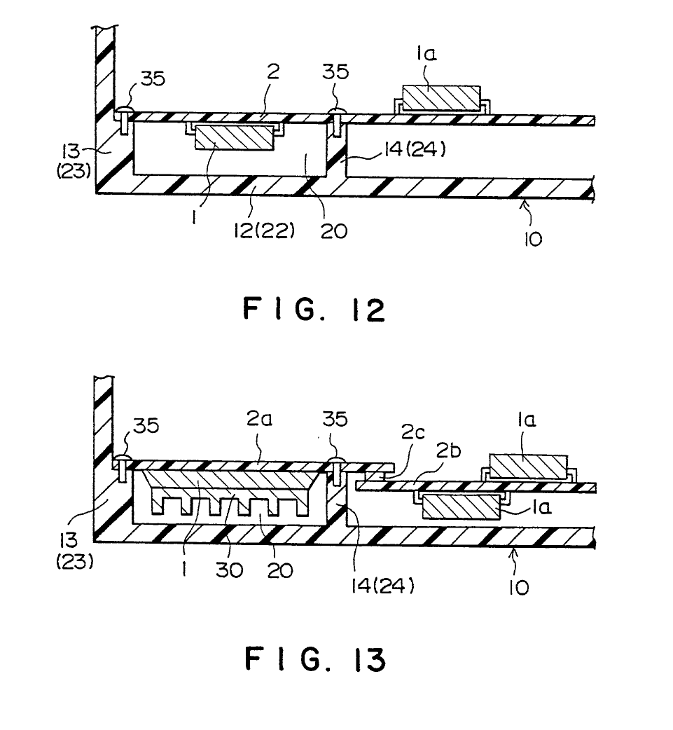

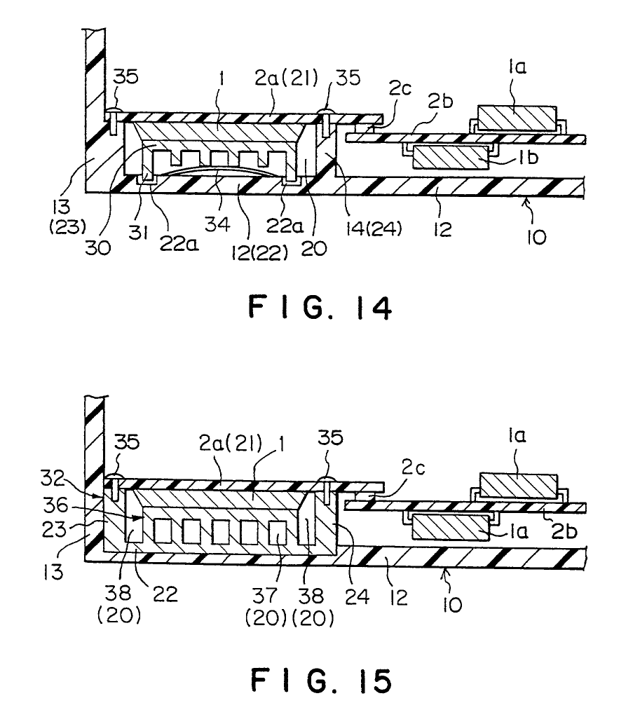

A notebook PC in a second embodiment according to the present invention will be described with reference to FIGS. 9 to 15.

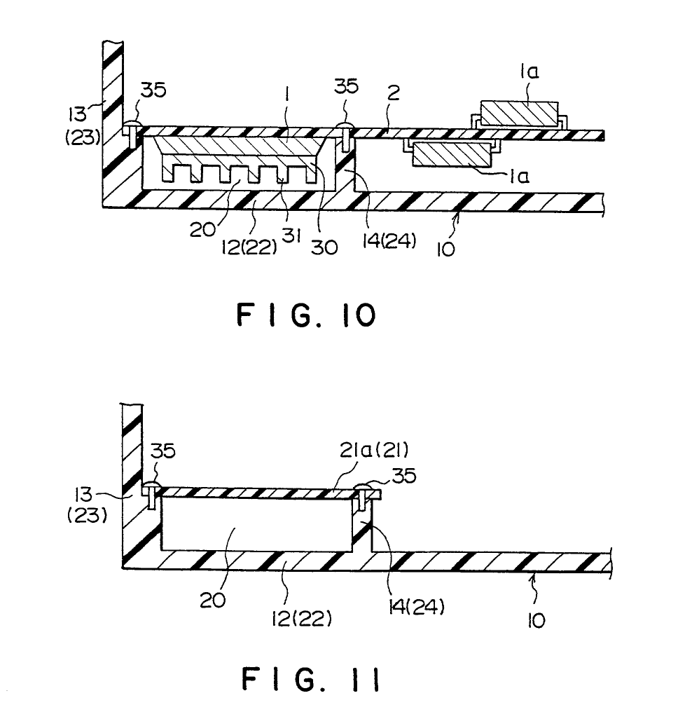

Referring to FIGS. 9 and 10, a top wall 21, i.e., one of members defining an air passage 20, is formed by fitting a part of a circuit board 2 in a recess formed in a plate 21a. Thus, a part of the top wall 21 is formed of the part of the circuit board 2.

The other part of the top wall 21 is formed of one or more than one plateshaped member, e.g., plate 21a, as shown in FIG. 11. The plate 21a may be a member specially for use as the top wall 21 or may be a metal or resin frame of an electronic device or a part of the same, or a shielding plate or a part of the same. The circuit board 2 and the plate 21a are fastened to a case 10 with screws 35.

As shown in FIG. 10, a heat-generative part (semiconductor device) 1 is attached to the lower surface of the circuit board 2 so as to be disposed in the air passage 20. Indicated at 1a in FIG. 10 are semiconductor devices which generate heat at a relatively low rate. A heatsink 30 is bonded to the heat-generative part 1 with a heat-conductive adhesive for the efficient dissipation of heat generated by the heat-generative part 1. The heatsink 30 has a plurality of fins 31 projecting downward in the air passage 20. The fins 31 are arranged in a wide range across the air passage 20, i.e., a lateral range as viewed in FIG. 10, and the edges of the fins 31 extend near a bottom wall 22. Cooling air flows efficiently through spaces between the fins 31 in the air passage 20. The heatsink 30 may be omitted as show in FIG. 12. Whether the heatsink 30 is necessary or not may be decided on the basis of general consideration of conditions including the heat generating characteristic of the heat-generative part 1 and the strength of attachment of the heat-generative part 1 to the circuit board 2.

The operation of the second embodiment will be described below. The fan 6 is driven for operation to produce currents of cooling air in the air passage 20. Heat generated by the heat-generative part 1 disposed in the air passage 20 is transferred directly from the heat-generative part 1 and indirectly through the heatsink 30 attached to the heat-generative part 1 to the cooling air. Thus the efficiency of cooling the heat-generative part 1 is increased.

The electronic apparatus in the second embodiment is provided with the single circuit board 2. The electronic apparatus may be provided with a first circuit board 2a mounted with component parts 1a which generate heat at a low rate and a second circuit board 2a mounted with heat-generative component parts 1 which generate heat at a high rate, the first circuit board 2a and the second circuit board 2b may be connected by a connector 2c in a stepped arrangement, and only a part of the second circuit board 2b may be used as a part of the top wall 21. When the two circuit boards 2a and 2b are used, the air passage 20 can be formed in an increased height without increasing the thickness of a space between the first circuit board 2a of a large area and the bottom wall 12 of the case 10, and the heatsink 30 may be provided with fins 31 of a great height. Accordingly, the main unit M can be formed in a thin structure.

A heatsink 30 as shown in FIG. 14 may thermally be connected to the heat-generative part 1 without bonding the heatsink 30 to the heat-generative part 1 with the heat-conductive adhesive. Referring to FIG. 14, the heatsink 30 is provided with fins 31 including fins 31 disposed at the opposite ends of the heatsink 30, respectively, and having a height greater than that of the rest of the fins 31. A pair of longitudinal grooves 22a are formed in the inner surface of the bottom wall 12 of the case 10, i.e., a bottom wall 22. A plate spring 34, which may be substituted by an elastic rubber sheet or the like, is placed between the middle fins 31 and the bottom wall 22, and then the first circuit board 2a is fastened to the side walls 23 and 24 of the duct structure with screws 35. Consequently, the heatsink 30 is pressed against the heat-generative part 1 by the plate spring 34, so that the heatsink 30 is positioned with respect to a vertical direction. Since the fins 31 at the opposite ends of the heatsink 30 are inserted in the grooves 22a, respectively, the heatsink 30 is restrained from lateral movement as viewed in FIG. 14. A heat-conductive sheet or a heat-conductive grease layer is interposed between the respective contact surfaces of the hat-generative part 1 and the heatsink 30 to improve heat transfer efficiency.

Although the bottom wall 22 and the side walls 23 and 24 of the duct structure defining the air passage 20 in the second embodiment are a part of the bottom wall 12, a part of the side wall 13 and a part of the rib 14 of the case 10, a duct structure having an air passage may be defined by walls other than the walls 12 and 13 and the rib 14 of the case 10.

For example, In a duct structure shown in FIG. 15, a heat-generating part 1 may be covered with a covering member 32 having a generally U-shaped cross section. The circuit board 2a is fastened to the covering member 32 with screws 35. The circuit board 2a serves as the top wall 21, a pair of side portions of the covering member 32 serve as the side walls 23, 24, and the bottom portion of the covering member 32 serves as the bottom wall 22, respectively. Preferably, the covering member 32 provided with a protuberance 36 integrally formed with the covering member 32. Cavities 37 are formed in the protuberance 36, and a top face of the protuberance 36 is in contact with the heat-generative part 1. Accordingly, the protuberance 36 with cavities 38 accomplishes the function of the heatsink 30, without fins susceptible to be damaged. The protuberance 36 is very solid because of its construction, thus the protuberance 36 is not damaged even if it strikes other component parts when assembling the notebook PC.

In this duct structure, cavities 37 and spaces 38 form part of the air passage 20. In other words, cavities 37 and spaces 38 are connected to other part of the air passage 20 defined by the walls 12 and 13 and the rib 14 (not shown in FIG. 15) of a case 10 and the plate-shaped member 21, e.g., first circuit board 2a, so as to form the continuous air passage 20.

Third Embodiment

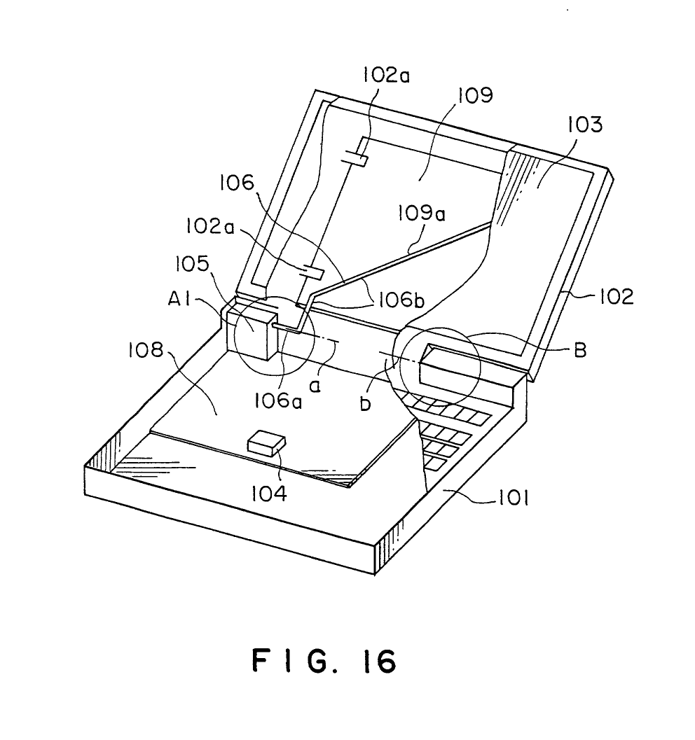

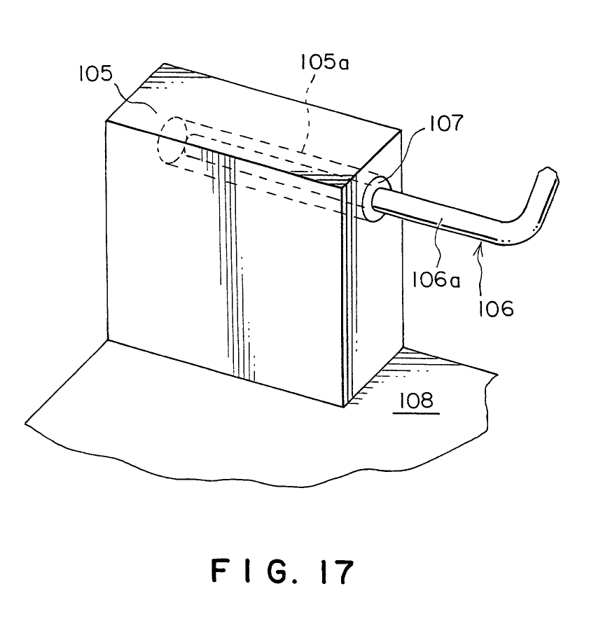

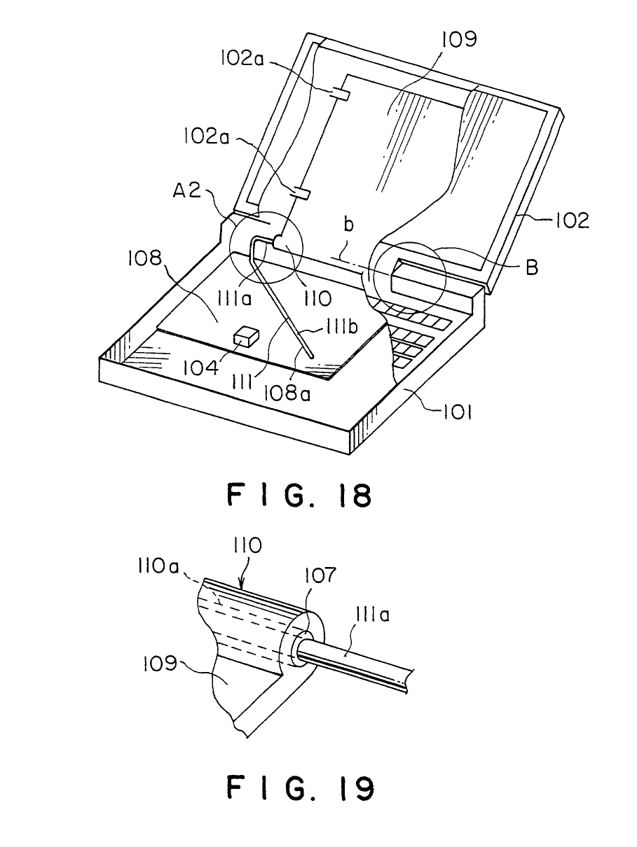

A notebook PC in a third embodiment according to the present invention will be described with reference to FIGS. 16 and 17. Referring to FIG. 16, the notebook PC has a main unit having a first case 101 containing a circuit board, not shown, mounted with component parts 104 which generate heat at a high rate, such as a MPU and a MCM (Multi-Chip Module) (hereinafter referred to as “heat-generative parts”), a power unit, a battery, a HDD or a DVD (Digital Versatile Disk), which are not shown in FIG. 16, and a display unit having a second case 102 containing a LCD (Liquid Crystal Display) 103 and a light source, not shown, and such.

The first case 101 and the second case 102 are pivotally joined together by a hinge joint B. The hinge joint B comprises a pivot pin (not shown) fixed to the first case 101 (or the second case 102), and a bearing member (not shown) fixed to the second case 102 (or the first case 101) and receiving the pivot pin. A plurality of wires are extended through the hinge joint B to send signals and to supply power from component parts contained in the first case 101 to the LCD 103 contained in the second case 102. The hinge joint B is of a conventional construction.

A heat dissipating structure included in the notebook PC in the third embodiment includes a heat radiating plate (heat radiating means) 109 of a heatconductive material, such as aluminum, placed in the second case 102, and a heat transfer structure thermally connecting the heat-generative parts 104 contained in the first case 101 to the heat radiating plate 109.

The heat radiating plate 109 is disposed in close contact with a wall of the second case 102 behind the LCD 103 and is fixedly or movably held in place on the second case 102 with fingers 102a formed integrally with the second case 102.

The heat transfer structure has a heat transfer plate 108 fixedly held on the bottom surface of the first case 101 and thermally connected to the heat-generative parts 104, a bearing member 105 bonded to the heat transfer plate 108 with a heat-conductive adhesive, and a substantially completely round heat pipe (heat transfer member) 106 connected to the heat radiating plate 109 held in the second case 102. The heat transfer plate 108 and the bearing member 105 are made of materials having a high thermal conductivity, such as metals. The bearing member 5 may be formed integrally with the heat transfer plate 108.

As shown in FIG. 16, the heat pipe 106 has a part 106a aligned with the axis b of turning of the hinge joint B, and a part 106b. The part 106a of the heat pipe 106 is substantially perpendicular to the part 106b. The part 106b is bent so as to extend along a diagonal of the heat radiating plate 109. The portion of the part 106b extending along the diagonal of the heat radiating plate 109 is fixedly pressed in a groove 109a formed in the heat radiating plate 109 to connect the heat pipe 106 thermally and mechanically to the heat radiating plate 109.

The bearing member 105 is provided with a bore 105a of a diameter slightly greater than the outside diameter of the heat pipe 106. An end portion of the part 106a of the heat pipe 106 is fitted for turning in the bore 105a of the bearing member 105. The clearance between the respective surfaces of the heat pipe 106 and the bore 105a of the bearing member 105 is filled up with a heat-conductive grease 107 to reduce thermal contact resistance (resistance to heat transfer).

A hinge joint is constructed by the part 106a of the heat pipe 106 fixed to the second case 102 via the heat radiating plate 109, and by the bearing member 105 fixed to the second first case via the heat transfer plate 108. The axis a of turning of the hinge joint A1, i.e., the center axis of the bore 105a, is aligned with the axis b of turning of the hinge joint B. The hinge joints A1 and B construct a joint structure pivotally connecting the first case 101 and the second case 102 for turning relative to each other. Thus, the second case 102 is hinged to the first case 101 by the hinge joints A1 and B.

Heat generated by the heat-generative parts 104 contained in the first case 101 is transferred through the heat transfer plate 108, the bearing member 105 and the heat pipe 106 to the heat radiating plate 109 contained in the second case 102, and is radiated outside from the heat radiating plate 109. The heat dissipating efficiency of this heat dissipating structure is far higher than that of a heat dissipating structure constructed only in the first case 101.

Although this embodiment employs the heat pipe 106 as a heat transfer member, the heat dissipating structure may be provided with a heat transfer member made of a heat-conductive material, such as a metal, and having a part of the same shape as the part 106a of the heat pipe 106 fitted in the bore 105a of the bearing member 105 instead of the heat pipe 106. The shape of parts of the heat transfer member other than the part corresponding to the part 106a of the heat pipe 106 may be formed in any suitable shape.

Although the portion of the part 106b of the heat pipe 106 fixed to the heat radiating plate 109 is straight and is extended along the diagonal of the heat radiating plate 109 in this embodiment, the same portion of the part 106b fixed to the heat radiating plate 109 may be formed in a zigzag or meandering shape. The portion of the part 106b of the heat pipe 106 need not necessarily be pressed in the groove formed in the heat radiating plate 109, the heat pipe 109 may be connected to the heat radiating plate 109 by placing the portion of the part 106b of the heat pipe 106 on the heat radiating plate 109, covering the same portion with a thin metal sheet, and bonding the metal sheet and the portion of the part 106b of the heat pipe 106 to the heat radiating plate 109 with a heat-conductive adhesive.

The second case 102 may be used as a heat radiating means instead of the heat radiating plate 109 attached to the second case 102 if the second case is made of a material having a high thermal conductivity.

Fourth Embodiment

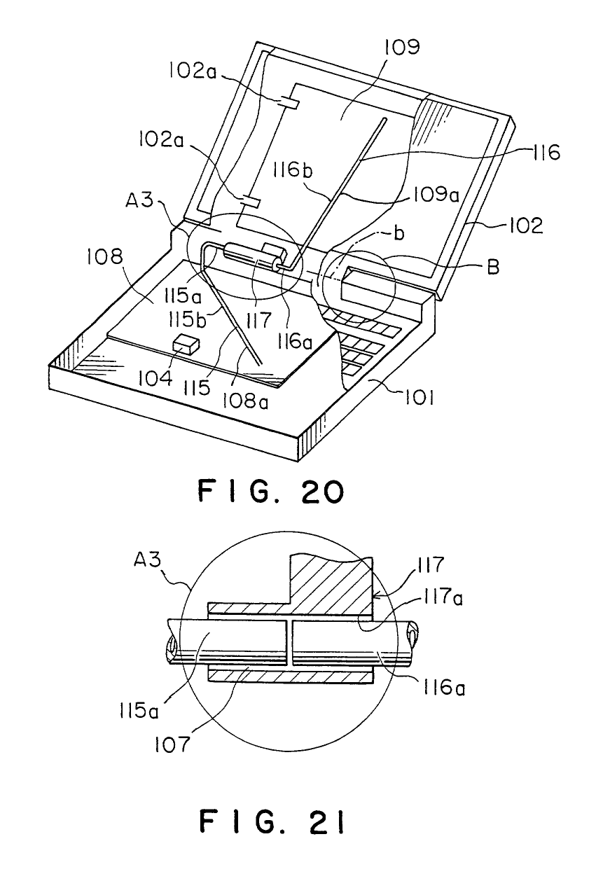

A notebook PC in a fourth embodiment according to the present invention will be described with reference to FIGS. 18 and 19.

Referring to Fig. 18, a heat transfer structure employed in the fourth embodiment comprises a heat transfer plate 108 thermally connected to a heatgenerative part 104 fixedly placed in a first case 101, a heat radiating plate 109 fixedly held on a second case 102 by fingers 102a, a bearing member 110 formed integrally with the heat radiating plate 109, and a substantially completely round heat pipe (heat transfer member) 111 having a part 111b connected to the heat transfer plate 108 and a part 111a connected to the bearing member 110. The part 111b of the heat pipe 111 is fixedly pressed in a groove 108a formed in the heat transfer plate 108. The bearing member 110 is provided with a bore 110a of a diameter slightly greater than the outside diameter of the heat pipe 111. The part 111a of the heat pipe 111 is fitted for turning in the bore 110a of the bearing member 110. The clearance between the respective surfaces of the heat pipe 111 and the bore 110a of the bearing member 110 is filled up with a heat-conductive grease 107.

The part 111a (which serves as a pivot pin) of the heat pipe 111 fixed to the heat transfer plate 108 contained in the first case 101, and the bearing member 110 formed integrally with the heat radiating plate 109 fixedly held on the second case 102 construct a hinge joint A2. The axis of turning of the hinge joint A2, i.e., the center axis of the bore 110a , is aligned with the axis b of turning of a hinge joint B. The hinge joints A2 and B construct a joint structure pivotally connecting the first case 101 and the second case 102 for turning relative to each other.

Heat generated by the heat-generative part 104 contained in the first case 101 is transferred through the heat transfer plate 108, the heat pipe 111 and the bearing member 110 to the heat radiating plate 109 contained in the second case 102, and is radiated outside from the heat radiating plate 109. The heat radiating plate 109 and the bearing member may separately be fabricated and may be bonded together with a heat-conductive adhesive.

Fifth Embodiment

A notebook PC in a fifth embodiment according to the present invention will be described with reference to FIG. 20.

Referring to FIG. 20, a heat transfer structure employed in the fifth embodiment comprises a heat transfer plate 108 thermally connected to a heat-generative part 104 fixedly placed in a first case 101, a substantially completely round first heat pipe 115 fixed to the heat transfer plate 108, a substantially completely round second heat pipe 116 fixed to a heat radiating plate 109 fixedly held in a second case 102, and a bearing member 117 provided with a bore receiving end parts of the first heat pipe (heat transfer member) 115 and the second heat pipe (heat transfer member) 116. The bearing member 117 is fixed to the second case 102. The bearing member 117 is provided with a bore 117a of a diameter slightly greater than the outside diameter of the heat pipes 115 and 116. Parts 115a and 116a (which serve as pivot pins) of the heat pipes 115 and 116 are fitted for turning in the bore 117a of the bearing member 117. The clearances between the respective surfaces of the heat pipe 115 and the bore 117a of the bearing member 117 and between the respective surfaces of the heat pipe 116 and the bore 117a of the bearing member 117 are filled up with a heat-conductive grease 107.

The part 115a (which serves as a pivot pin) of the heat pipe 115 fixed to the heat transfer plate 108 fixedly held in the first case 101, the part 116a (which serves as a pivot pin) of the heat pipe 116 fixed to the heat radiating plate 109 fixedly held in the second case 102, and the bearing member 117 construct a hinge joint A3. The axis of the hinge joint A3, i.e., the center axis of the bore 117a, is aligned with the axis b of the hinge joint B. The hinge joints A3 and B construct a joint structure pivotally joining together the first case 101 and the second case 102. Heat generated by the heat-generative part 104 contained in the first case is transferred through the heat transfer plate 108, the heat pipe 115, the bearing member 117 and the heat pipe 116 to the heat radiating plate 109 contained in the second case 102, and is radiated from the heat radiating plate 109.

The bearing member 117 may be fixed to the first case 101 instead of fixing the same to the second case 102. The heat pipe 115 may directly and thermally be connected to the heat-generative part 104 contained in the first case 101 instead of connecting the same through the heat transfer plate 108 to the heat-generative part 104.

The heat pipe 115 may be omitted and a member to be fitted in the bore 117a of the bearing member 117 may be formed integrally with the heat transfer plate 108. Similarly, the heat pipe 116 may be omitted and a member to be fitted in the bore 117a of the bearing member 117 may be formed integrally with the heat radiating plate 109. The member formed integrally with the heat transfer plate 108 or the heat radiating plate 109 may be of any suitable shape provided that a part of the member to be fitted in the bore 117a of the bearing member 117 has a cylindrical shape.

Sixth Embodiment

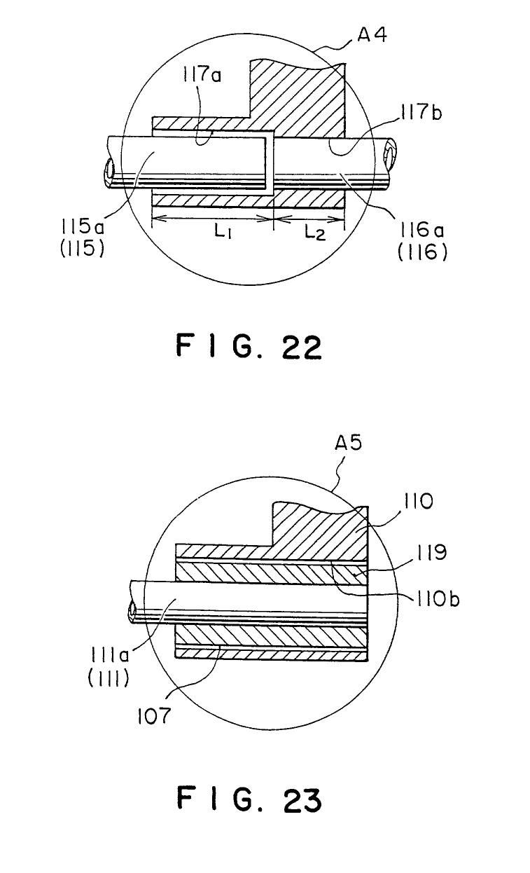

A notebook PC in a sixth embodiment according to the present invention will be described with reference to FIG. 22.

Referring to FIG. 22, a bearing member 117 is provided with a first bore 117a for receiving a part 115a of a first heat pipe 115 and a bore 117b for receiving a part 116a of a second heat pipe 116. The diameter of the first bore 117a is greater than the outside diameter of the part 115a of the first heat pipe 115. A clearance between the part 115a of the first heat pipe 115 and the first bore 117a is filled with a heat-conductive grease 107. The diameter of the second bore 117b is approximately equal to the outside diameter of the part 116a of the second heat pipe 116. The part 116a of the second heat pipe 116 is fitted in the second bore 117b in a push fit or a press fit. The first heat pipe 115 and the bearing member 117 construct a hinge joint A5.

Heat generated by a heat-generative part 104 contained in a first case 101 is transferred through a heat transfer plate 108, the first heat pipe 115, the bearing member 117 and the second heat pipe 116 to a heat radiating plate 109 contained in a second case 102, and is radiated from the heat radiating plate 109. According to this embodiment, resistance to heat transfer between the second heat pipe 116 and the bearing member 117 decreased.

The part 116a of the second heat pipe 116 may be fitted in the second bore 117b of the bearing member in a running fit and fixed to the bearing member 117 with solder or a heat-conductive adhesive instead of fitting the part 116a of the second heat pipe 116 in the second bore 117b of the bearing member in a push fit or a press fit.

It is preferable that the length L1 of a portion of the part 115a of the first heat pipe 115 fitted in the first bore 117a of the bearing member 117 is greater than the length L2 of a portion of the part 116a of the second heat pipe 116 fitted in the second bore 117b of the bearing member 117 so that the area of contact between the part 115a of the first heat pipe 115 and the bearing member 117 is greater than that between the part 116a of the second heat pipe 116 and the bearing member 117 because heat is transferred from the first heat pipe 115 to the bearing member 117 at a heat transfer efficiency lower than that at which heat is transferred from the bearing member 117 to the second heat pipe 116.

Seventh Embodiment

A notebook PC in a seventh embodiment according to the present invention will be described with reference to FIG. 23.

Referring to FIG. 23, a hinge joint A5 includes a heat pipe 111 thermally connected to a heat transfer plate 108 contained in a first case 101, a bearing member 110 of a material having a high thermal conductivity, such as aluminum, thermally connected to a heat radiating plate 109 contained in a second case 102, and a sleeve 119. The inside diameter of the sleeve 119 is approximately equal to the outside diameter of the heat pipe 111.

A part of the heat pipe 111 is fixedly fitted in the sleeve 119 in a push fit or a press fit. The outside diameter of the sleeve 119 is smaller than the diameter of a bore 110b formed in the bearing member 110. The sleeve 119 is fitted in the bore 110b of the bearing member 110 in a running fit, and a clearance between the sleeve 119 and the bore 110b of the bearing member 110 is filled up with a heat-conductive grease 107.

Heat generated by a heat-generative part 104 contained in a first case 101 is transferred through a heat transfer plate 108, the heat pipe 111, the sleeve 119 and the bearing member 110 to a heat radiating plate 109 contained in a second case 102, and is radiated from the heat radiating plate 109.

Since the area of the outer circumference of the sleeve 119 in contact with the bearing member 110 is greater than that of the corresponding portion of a part 111a of the heat pipe 111, the resistance to heat transfer from the heat-generative part to the heat radiating plate 109 can be reduced. The sleeve 119 bearing a stress induced in the hinge joint A5 enhances the strength of the hinge joint A5. The construction of the hinge joint A5 may be applied to the hinge joint A1 employed in the first embodiment for the same effect.

Eighth Embodiment

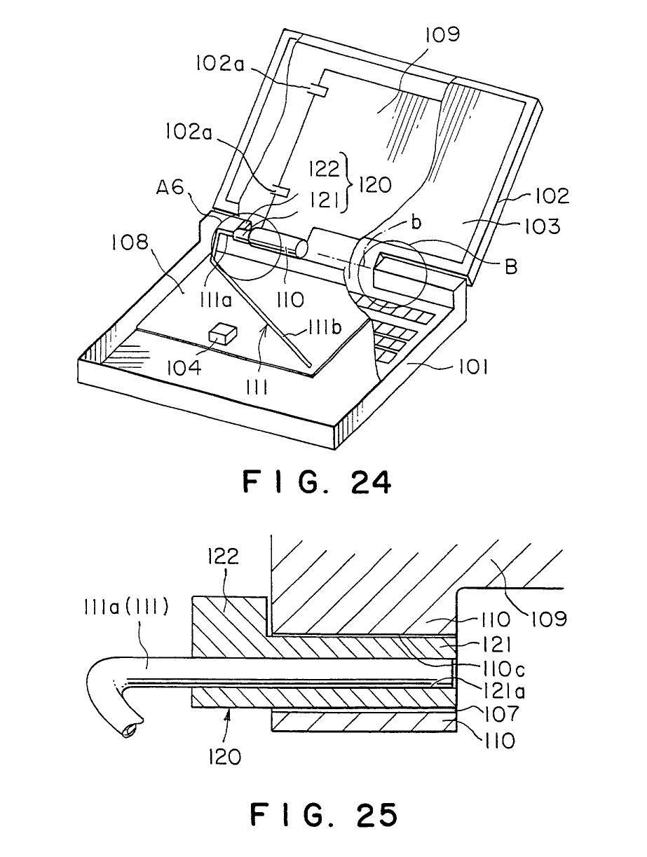

A notebook PC in an eighth embodiment according to the present invention will be described with reference to FIGS. 24 and 25.

Referring to FIG. 24, a heat transfer structure comprises a heat transfer plate 108 contained in a first case 101, a heat pipe 111 thermally connected to the heat transfer plate 108, a bearing member 110 of a heat-conductive material, such as aluminum, thermally connected to a heat radiating plate 109 contained in a second case 102, and a sleeve 120 having a cylindrical body part 121 provided with a bore 121a, and a head 122. The diameter of bore 121a of the body part 121 of the sleeve 120 is approximately equal to the outside diameter of the heat pipe 111. A part 111a of the heat pipe 111 is fixedly fitted in the bore 121a of the sleeve 120 in a push fit or a press fit. The outside diameter of the body part 121 of the sleeve 120 is smaller than the diameter of a bore 110c formed in the bearing member 110. The body part 121 of the sleeve 120 is fitted in the bore 110c of the bearing member 110 in a running fit, and a clearance between the body part 121 of the sleeve 120 and the bore 110c of the bearing member 110 is filled up with a heat-conductive grease 107. The head 122 of the sleeve 120 is fixed to the first case 101.

The sleeve 120 fixed to the first case 101, and the bearing member 110 construct a hinge joint A6. The axis of turning of the hinge joint A6, i.e., the center axis of the bore 110c, is aligned with the axis b of turning of a hinge joint B. The hinge joints A6 and B construct a joint structure pivotally connecting the first case 101 and the second case 102 for turning relative to each other.

Heat generated by a heat-generative part 104 contained in a first case 101 is transferred through a heat transfer plate 108, the heat pipe 111, the sleeve 120 and the bearing member 110 to the heat radiating plate 109 contained in the second case 102, and is radiated from the heat radiating plate 109.

Radial load on the hinge joint A6 can be borne by the sleeve 120 fixed to the first case 101, and the bearing member 110 fixed to the second case 102, so that only a reduced stress is induced in the heat pipe 111. Accordingly, any stress will not be induced in the heat-generative part 104 even if the heat pipe 111 is connected directly to the heat-generative part 104 instead of through the heat transfer plate 108 fixedly held on the first case 101.

The construction of the hinge joint A6 employed in the eighth embodiment can be applied to the third embodiment. In the third embodiment, the heat pipe 106 may be fixedly fitted in the bore of the body part of a sleeve substantially the same in construction as the sleeve 120 having the body part 121 and the head 122, the sleeve may be fitted in the bore of the bearing member 105 in a running fit, and the head of the sleeve may be fixed to the second case 102.

Ninth Embodiment

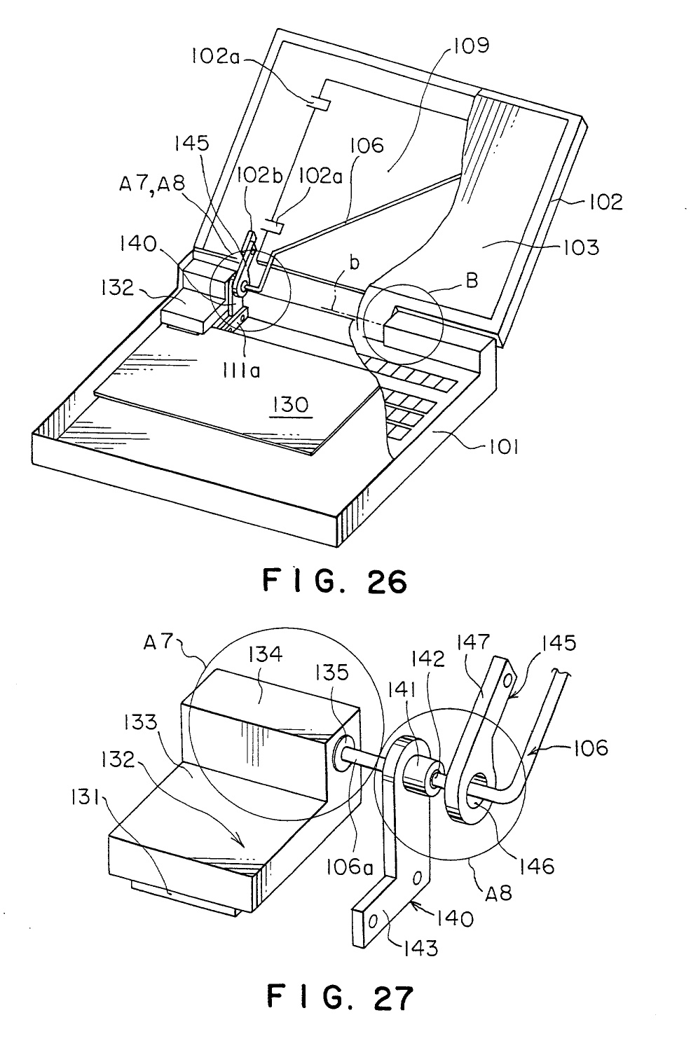

A notebook PC in a ninth embodiment according to the present invention will be described with reference to FIGS. 26 and 27.

Referring to FIGS. 26 and 27, a notebook PC is provided with a MCM 132, i.e., a heat-generative part, and the MCM 132 is contained in a first case 101. The MCM 132 is connected to a motherboard (circuit board) 130 by a connector 131. The MCM 132 has a cap 133, and a bearing member 134 is formed integrally with the cap 133. The cap 133 is made of a heat-conductive material, such as aluminum, to transfer efficiently heat generated by a chip contained in the cap 133 of the MCM 132. The cap 133 is fixed to the first case 101. The bearing member 134 is provided with a bore. A part 106a of a substantially perfectly round heat pipe 106 is fitted in a sleeve 135, and the sleeve 135 is fitted in a bore 134a formed in the bearing member 134. Another part 106b of the heat pipe 106 is connected to a heat radiating plate 109. The cap 133, the bearing member 134 and the heat pipe 106 construct a heat transfer structure. The inside diameter of the sleeve 135 is approximately equal to the outside diameter of the part 106a of the heat pipe 106, and part 106a of the heat pipe 106 is fitted in the sleeve 135 in a push fit or a press fit so that the part 106a of the heat pipe 106 is fixed to the sleeve 135. The outside diameter of the sleeve 135 is smaller than the diameter of the bore 134a of the bearing member 134, and the sleeve 135 is fitted in the bore 134a of the bearing member 134 in a running fit, and a clearance between the sleeve 135 and the bore 134a of the bearing member 134 is filled up with a heat-conductive grease 107. The bearing member 134, the sleeve 135 and the part 106a of the heat pipe 106 fixedly fitted in the bore of the sleeve 135 construct a hinge joint A7.

As shown in FIGS. 26 and 27, the notebook PC is provided with a hinge joint A8 disposed near the hinge joint A7. The hinge joint A8 has a first member 140 and a second member 145. The first member 140 has an annular boss 141 provided with a through hole 142 of a diameter far greater than the outside diameter of the heat pipe 136, and a leg 143 fastened to a bracket 101a formed integrally with the first case 101.

The second member 145 is provided with a through hole 146 of a diameter slightly greater than the outside diameter of the boss 141 of the first member 140. The second member 145 has an arm 147. The arm 147 is fastened to a bracket 102b formed integrally with a second case 102. The boss 141 is fitted in the through hole 146 of the second member 145 to connect the first member 140 and the second member 145 pivotally so that the second member 145 is able to turn relative to the first member 140. The part 106a of the heat pipe 106 is extended through the through hole 142 of the boss 141 of the first member 140 and the through hole 146 of the second member 145.

The respective axes of turning of the hinge joints A7 and A8 are aligned with the axis b of a hinge joint B. The hinge joints A7, A8 and B construct a joint structure joining together the first case 101 and the second case 102 for turning relative to each other. The class of the fit between the component parts of the hinge joint A7, i.e., between the bearing member 134 and the sleeve 135, is lower than the class of the fit between the component parts of the hinge joint A8, i.e., the boss 141 of the first member 140 and the second member 145, and the class of the fit between the component parts of the hinge joint B. Therefore, radial load exerted on the joint structure joining together the first case 101 and the second case 102 is borne by the hinge joints A8 and B formed in a tight, strong construction, and the hinge joint A7 is not loaded substantially. Therefore, the breakage of the MCM 132 can be prevented.

Heat generated by the plurality of component chips (heat-generative parts) of the MCM 132 is transferred through the cap 133, the sleeve 135 and the heat pipe 106 to the heat radiating plate 109 and is radiated from the heat radiating plate 109.

The first member 140 and the second member 145 of the hinge joint A8 may be fixed to the second case 102 and the first case 101, respectively. Either the first member 140 or the second member 145 may be formed integrally with either the first case 101 or the second case 102, or both the first member 140 and the second member 145 may be formed integrally with the first case 101 (the second case 102) and the second case 102 (the first case 101), respectively. The hinge joint A8 may be disposed apart from the heat pipe 106 without extending the heat pipe 106 through the through hole 142 of the boss 141 of the first member 140. The hinge joint A7 may be constructed at a position between the hinge joints B and A8.

Tenth Embodiment

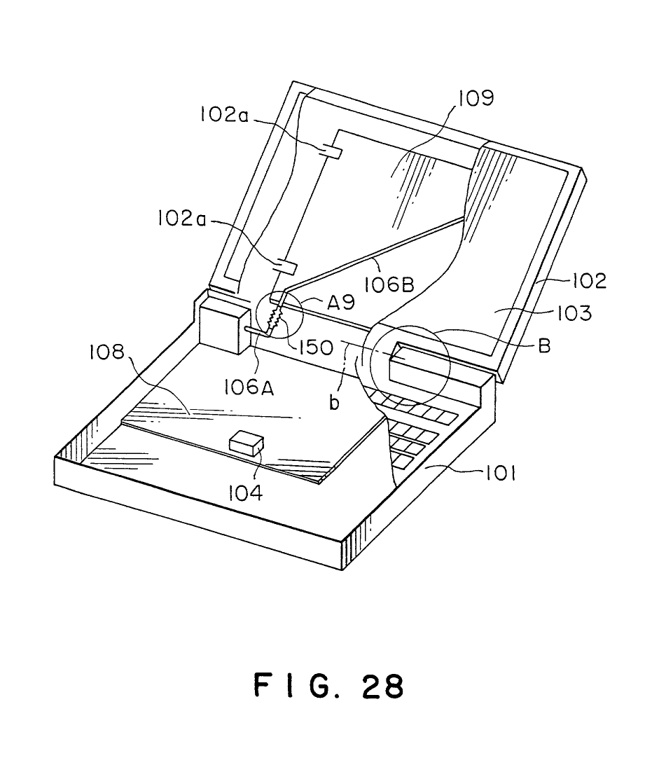

A notebook PC in a tenth embodiment according to the present invention will be described with reference to FIG. 28.

Referring to FIG. 28, a heat pipe 106 is divided into a first part 106A and a second part 106B, and the first part 106A and the second part 106B are connected together by a bellows expansion joint 150 serving as a flexible joint A9. The bellows expansion joint 150 is disposed substantially on an extension of the axis b of turning of a hinge joint B. The part 106A of the heat pipe 106 is pressed in a bore 105a formed in a member 105. The member 105 does not function as a bearing member and serves merely a heat transferring member. The part 106B of the heat pipe 106 is connected to a heat radiating plate 109. Only the hinge joint B serves as a joint structure pivotally joining together a first case 101 and a second case 102 for turning relative to each other. When the second case 102 is turned relative to the first case 102 to close the notebook PC, the bellows expansion joint 150 bends not to obstruct the action of the hinge joint B.

Heat generated by a heat-generative part 104 contained in the first case 101 is transferred through a heat transfer plate 108, the member 105, the part 106A of the heat pipe 106, the bellows expansion joint 150 and the part 106B of the heat pipe 106 to a heat radiating plate 109 contained in the second case 102 and is radiataed from the heat radiating plate 109.

Preferably, the hinge joint A8 of the ninth embodiment is disposed near the flexible joint A9 to construct a joint structure by the two hinge joints A8 and B in order that load on the hinge joint B is reduced.

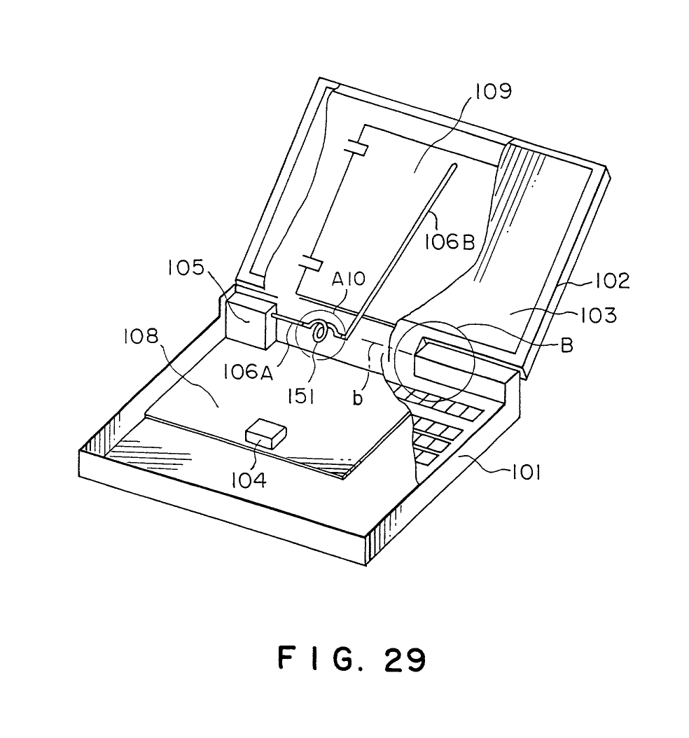

As shown in FIG. 29, a flexible connecting member 151 having helical coils formed by coiling a wire of a heat-conductive, elastic material, such as an elastic metal, may be employed instead of the bellows expansion joint 150. The flexible connecting member 151 is disposed with the axis of the helical coils thereof substantially aligned with an extension of the axis b of turning of the hinge joint B. When the second case 102 is turned relative to the first case 101 to close the notebook PC, the flexible connecting member 151 is deformed elastically not to obstruct the action of the hinge joint B.

When the flexible connecting member 151 is employed, heat generated by the heat-generative part 104 contained in the first case 101 is transferred through a heat transfer plate 108, the member 105, the part 106A of the heat pipe 106, the flexible connecting member 151 and the part 106B of the heat pipe 106 to the heat radiating plate 109 contained in the second case 102 and is radiated from the heat radiating plate 109. Thus, the effect of the modification shown in FIG. 29 of the tenth embodiment shown in FIG. 28 is the same as that of the tenth embodiment shown in FIG. 28.

Preferably, the hinge joint A8 employed in the ninth embodiment is disposed at a position near the flexible joint A10 and between the member 105 and the flexible member 151.

Eleventh Embodiment

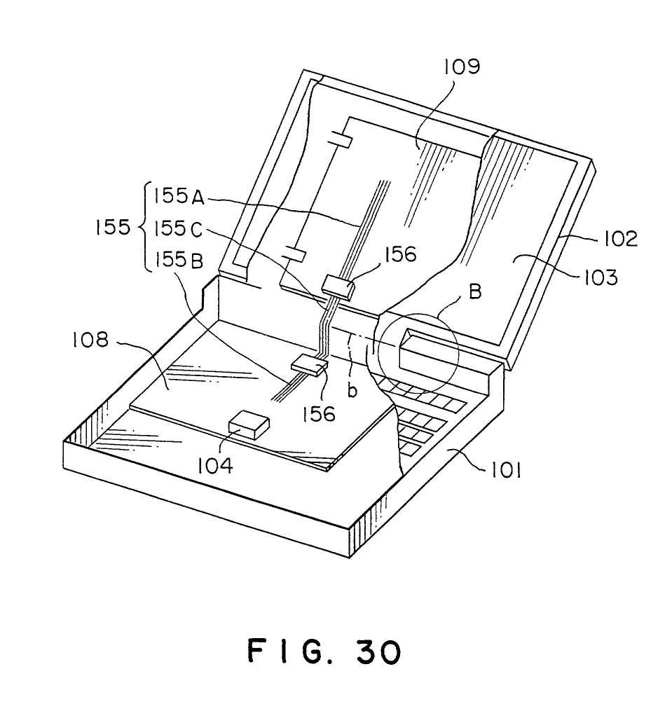

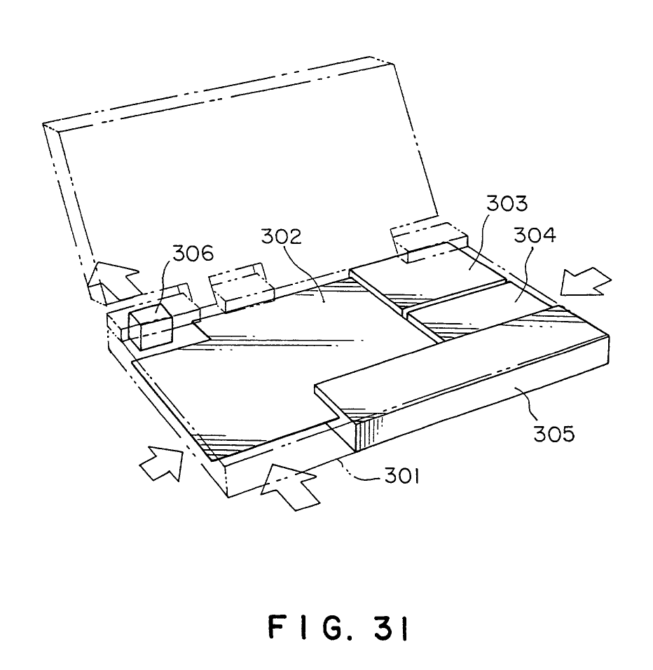

A notebook PC in an eleventh embodiment according to the present invention will be described with reference to FIG. 30.

Referring to FIG. 30, a carbon fiber bundle 155 having carbon fibers has a first part 155A bonded to a heat radiating plate 109 with a heat-conductive adhesive, a second part 155B bonded to a heat transfer plate 108 with a heat-conductive adhesive, and a third part 155C between the first part 155A and the second part 155B. The third part 155C of the carbon fiber bundle 155 is bundled at its opposite ends by clasps 156 so that the carbon fibers are able to move individually and the third part 155C can be distorted.

When a second case 102 is turned relative to the first case 101 to close the notebook PC, the third part 155C of the carbon fiber bundle 155 is distorted accordingly not to obstruct the action of a hinge joint B. Heat generated by a heat-generative part 104 contained in the first case 101 is transferred through the heat transfer plate 108 and the carbon fiber bundle 155 to the heat radiating plate 109 contained in the second case 102, and is radiated from the heat radiating plate 109. Preferably, a hinge joint similar to the hinge joint A8 employed in the seventh embodiment is disposed near the carbon fiber bundle 155. An additional hinge joint similar to the hinge joint B and the hinge joint B may be disposed on the opposite sides of the carbon fiber bundle 155, respectively.

What is claimed is:

1. An electronic apparatus comprising:
a case containing a heat-generative part;
walls defining a passage in the case, the passage being adapted to carry a cooling medium therethrough;
a fan for producing a flow of the cooling medium in the passage; and
a heat transfer member for transferring a heat generated by the heat-generative part to the cooling medium flowing through the passage;
wherein a heat generated by the heat-generative part is conveyed outside the case by the cooling medium flowing through the passage.

2. The electronic apparatus according to claim 1, wherein the heat transfer member is connected to the wall, and the heat generated by the heat-generative part is transferred to the cooling medium flowing through the passage via the wall.

3. The electronic apparatus according to claim 1, wherein the heat transfer member is inserted into the passage through the wall, and at least part of the heat generated by the heat-generative part is directly transferred to the cooling medium flowing through the passage.

4. The electronic apparatus according to claim 1, wherein the heat transfer member is selected from the group consisting of a metal rod, a heat pipe and a carbon fiber bundle.

5. The electronic apparatus according to claim 1, wherein at least one of the walls defining the passage is formed of a heat-conductive material which is a metal or a ceramic material having a high thermal conductivity, and the heat transfer member is connected to the wall formed of the heat-conductive material,
and wherein the heat generated by the heat-generative part is transferred through the heat transfer member and the wall formed of the heat-conductive material to the cooling medium flowing through the passage.

6. The electronic apparatus according to claim 5, wherein the wall formed of a heat-conductive material is provided with fins projecting into the passage.

7. The electronic apparatus according to claim 1, wherein the heat transfer member is formed of an electrically conductive material and is electrically grounded.

8. The electronic apparatus according to claim 5, wherein the heat transfer member and the wall formed of the heat-conductive material are electrically conductive, and the electrically conductive wall is electrically grounded.

9. The electronic apparatus according to claim 1, wherein at least one of the walls is formed integrally with the case.

10. The electronic apparatus according to claim 1, wherein at least one of the walls is a frame or a shielding plate, having a plate-like shape and attached to the case.

11. An electronic apparatus comprising:
a case containing a heat-generative part;
walls defining a passage in the case, the passage being adapted to carry a cooling medium therethrough;
a fan for producing a flow of the cooling medium in the passage; and
a circuit board serving as one of the walls and disposed with a heat-generative part mounted thereon such that at least part of the heat-generating part lies in the passage;
wherein a heat generated by the heat-generative part is conveyed outside the case by the cooling medium flowing through the passage.

12. The electronic apparatus according to claim 11, wherein the circuit board serves as the wall defining a top of the passage, said apparatus further comprising:
a heatsink with fins disposed in the passage; and
an elastic member interposed between the wall defining a bottom of the passage and the fins of the heatsink, the elastic member having a elasicity in a direction perpendicular to the wall defining a bottom of the passage;
wherein when the circuit board is attached to the walls defining sides of the passage, the heatsink is pressed and held vertically against the heat-generative part.

13. The electronic apparatus according to claim 11, wherein part of the walls consist of a covering member attached to the circuit board and surrounding the heat-generative part,
and wherein the covering member is provided with a protuberance formed integrally with the covering member and connected to the heat-generative part, and the protuberance is provided with cavities therein serving as the passage.

14. An electronic apparatus comprising:
a first case containing a heat-generative part;
a second case connected to the first case;
a joint structure connecting together the first and the second case so that the first and the second case are able to turn relative to each other about a predetermined axis;
a heat radiating means provided at the second case; and
a hinge joint serving as at least part of the joint structure and being capable of transmitting heat, and the hinge joint having a bearing member thermally connected to one of both of the heat radiating means and the heat-generative part, and a heat transfer member having one side provided with a pivotal member pivotally fitted in the bearing member and the other side thermally connected to the other of both of the heat radiating means or the heat-generative part.

15. The electronic apparatus according to claim 14, wherein the pivotal member of the heat transfer member is provided with means for increasing area of heat transfer between the pivotal member and the bearing member.

16. The electronic apparatus according to claim 15, wherein the heat transfer member is a heat pipe, the heat transfer area increasing means is a cylindrical sleeve, the pivotal member included in the heat pipe is fitted in the sleeve, and the sleeve is supported on the bearing member.

17. The electronic apparatus according to claim 14, wherein the heat-generative part is an electronic part such as a micro process unit or a multi-chip module, having a cap fixed to the first case, and the bearing member is formed integrally with the cap.

18. The electronic apparatus according to claim 14 further comprising an additional hinge joint independent of the heat-conductive hinge joint and serving as part of the joint structure, the additional hinge joint having a bearing member fixed to one of both of the first and second cases and a pivotal member fixed to the other of both of the first and second cases,
wherein a class of a fit in which the pivotal member is fitted in the bearing member in the heat-conductive hinge joint is lower than that of a fit in which the pivotal member is fitted in the bearing member in the additional hinge joint.

19. An electronic apparatus comprising:
a first case containing a heat-generative part;
a second case connected to the first case;
a joint structure joining together the first and the second case so that the first and the second case are able to turn relative to each other about a predetermined axis;
a heat radiating means provided at the second case; and
a heat transfer member having opposite ends thermally connected respectively to the heat-generative part and the heat radiating means, the heat transfer member including a flexible section having a flexibility so as not to obstruct the turning of the first and the second case relative to each other.
